(19) United States
(12) Patent Application Publication
(10) Pub. No.: US 2010/0291763 A1
(43) Pub. Date: Nov. 18, 2010

(54) METHOD OF MANUFACTURING SEMICONDUCTOR DEVICE AND SUBSTRATE PROCESSING APPARATUS

(75) Inventors: Arito OGAWA, Toyama-shi (JP); Sadayoshi Horii, Toyama-shi (JP); Hideharu ITATANI, Toyama-shi (JP)

Correspondence Address: North Star Intellectual Property Law, PC, P.O. Box 34688, Washington, DC, 20043, US

(73) Assignee: HITACHI-KOKUSAI ELECTRIC INC., Tokyo (JP)

(21) Appl. No.: 12/781,488

(22) Filed: May 17, 2010

(30) Foreign Application Priority Data
May 18, 2009 (JP) 2009-120224

(51) Int. Cl. H01L 21/3205; H01L 21/31; B05C 11/10

(52) U.S. Cl. 438/584; 438/761; 118/704; 257/E21.24; 257/E21.295

(57) ABSTRACT

Oxidation of a metal film disposed under a high permittivity insulation film can be suppressed, and the productivity of a film-forming process can be improved. In a method of manufacturing a semiconductor device, a first high permittivity insulation film is formed on a substrate by alternately repeating a process of supplying a source into a processing chamber in which the substrate is accommodated and exhausting the source and a process of supplying a first oxidizing source into the processing chamber and exhausting the first oxidizing source; and a second high permittivity insulation film is formed on the first high permittivity insulation film by alternately repeating a process of supplying the source into the processing chamber and exhausting the source and a process of supplying a second oxidizing source different from the first oxidizing source into the processing chamber and exhausting the second oxidizing source.

### CROSS-REFERENCE TO RELATED PATENT APPLICATION

This U.S. non-provisional patent application claims priority under 35 U.S.C. §119 of Japanese Patent Application No. 2009-120224, filed on May 18, 2009, in the Japanese Patent Office, the entire contents of which are hereby incorporated by reference.

### BACKGROUND OF THE INVENTION

1. Field of the Invention

The present invention relates to a method of manufacturing a semiconductor device and a substrate processing apparatus.

2. Description of the Related Art

As metal-oxide-semiconductor field effect transistors (MOSFETs) become highly integrated and have high performance, the use of a high permittivity insulation film is under investigation. In addition, for a capacitor of a dynamic random access memory (DRAM), a high permittivity insulation film such as a HfO₂ film or a ZrO₂ film having a relative permittivity in the range from, for example, about 15 to about 20 is used. Such a HfO₂ film or ZrO₂ film can be formed by alternately repeating a process of supplying a Hf-containing or Zr-containing source into a processing chamber and exhausting the source from the processing chamber and a process of supplying an oxidizing source such as O₃ or H₂O into the processing chamber and exhausting the oxidizing source from the processing chamber while heating a substrate accommodated in the processing chamber to a temperature of 200° C. or higher.

However, if O₃ is used as an oxidizing source, a metal film such as a TiN film which is under layer of a high permittivity insulation film may be oxidized and changed in properties. In addition, if H₂O is used as an oxidizing source, due to a time necessary for exhausting the H₂O from a processing chamber, the productivity of a film-forming process may be decreased. Moreover, in the case of using H₂O as an oxidizing source, the properties of a high permittivity insulation film may be inferior to those of a high permittivity insulation film formed using O₃ as an oxidizing source.

### SUMMARY OF THE INVENTION

An object of the present invention is to provide a method of manufacturing a semiconductor device and a substrate processing apparatus, for suppressing oxidation of a metal film disposed under a high permittivity insulation film and improving the productivity of a film-forming process.

According to an aspect of the present invention, there is provided a method of manufacturing a semiconductor device, the method including:

forming a first high permittivity insulation film on a substrate by alternately repeating a process of supplying a source into a processing chamber in which the substrate is accommodated and exhausting the source from the processing chamber and a process of supplying a first oxidizing source into the processing chamber and exhausting the first oxidizing source from the processing chamber; and

forming a second high permittivity insulation film on the first high permittivity insulation film by alternately repeating a process of supplying the source into the processing chamber and exhausting the source from the processing chamber and a process of supplying a second oxidizing source different from the first oxidizing source into the processing chamber and exhausting the second oxidizing source from the processing chamber.

According to another aspect of the present invention, there is provided a method of manufacturing a semiconductor device, the method including:

forming a first high permittivity insulation film on a substrate by alternately repeating a process of supplying a source into a processing chamber in which the substrate is accommodated and exhausting the source from the processing chamber and a process of supplying H₂O into the processing chamber and exhausting the H₂O from the processing chamber; and

forming a second high permittivity insulation film on the first high permittivity insulation film by alternately repeating a process of supplying the source into the processing chamber and exhausting the source from the processing chamber and a process of supplying O₃ into the processing chamber and exhausting O₃ from the processing chamber.

According to another aspect of the present invention, there is provided a substrate processing apparatus including:

a processing chamber configured to process a substrate;

a source supply system configured to supply a source into the processing chamber;

a first oxidizing source supply system configured to supply a first oxidizing source into the processing chamber;

a second oxidizing source supply system configured to supply a second oxidizing source different from the first oxidizing source into the processing chamber;

an exhaust system configured to exhaust an inside of the processing chamber; and

a controller configured to control the source supply system, the first oxidizing source supply system, the second oxidizing source supply system, and the exhaust system, so as to:

form a first high permittivity insulation film on the substrate by alternately repeating a process of supplying the source into the processing chamber in which the substrate is accommodated and exhausting the source from the processing chamber and a process of supplying the first oxidizing source into the processing chamber and exhausting the first oxidizing source from the processing chamber; and

form a second high permittivity insulation film on the first high permittivity insulation film by alternately repeating a process of supplying the source into the processing chamber and exhausting the source from the processing chamber and a process of supplying the second oxidizing source into the processing chamber and exhausting the second oxidizing source from the processing chamber.

### BRIEF DESCRIPTION OF THE DRAWINGS

FIG. 1 is view illustrating a gas supply system of a first processing unit (high permittivity insulation film forming unit) of a cluster apparatus according to an embodiment of the present invention.

FIG. 2 is a schematic view illustrating the cluster apparatus according to an embodiment of the present invention.

FIG. 3 is a sectional view illustrating the first processing unit (high permittivity insulation film forming unit) of the cluster apparatus when a wafer is processed according to an embodiment of the present invention.

FIG. 4 is a sectional view illustrating the first processing unit (high permittivity insulation film forming unit) of the cluster apparatus when a wafer is carried according to an embodiment of the present invention.

FIG. 5 is a sectional view illustrating a second processing unit (heat treatment unit) of the cluster apparatus according to an embodiment of the present invention.

FIG. 6 is a flowchart for explaining a substrate processing process according to an embodiment of the present invention.

FIG. 7A and FIG. 7B are schematic views illustrating a vertical processing furnace of a vertical apparatus according to another embodiment of the present invention, in which FIG. 7A is a vertical sectional view illustrating the vertical processing furnace and FIG. 7B is a sectional view of the vertical processing furnace taken along line A-A of FIG. 7A.

FIG. 8 is a schematic sectional view illustrating a sample film formed according to an embodiment of the present invention.

### DETAILED DESCRIPTION OF THE PREFERRED EMBODIMENTS

Hereinafter, an embodiment of the present invention will now be described with reference to the attached drawings.

### (1) Structure of Substrate Processing Apparatus

First, a substrate processing apparatus will be described according to an embodiment of the present invention.

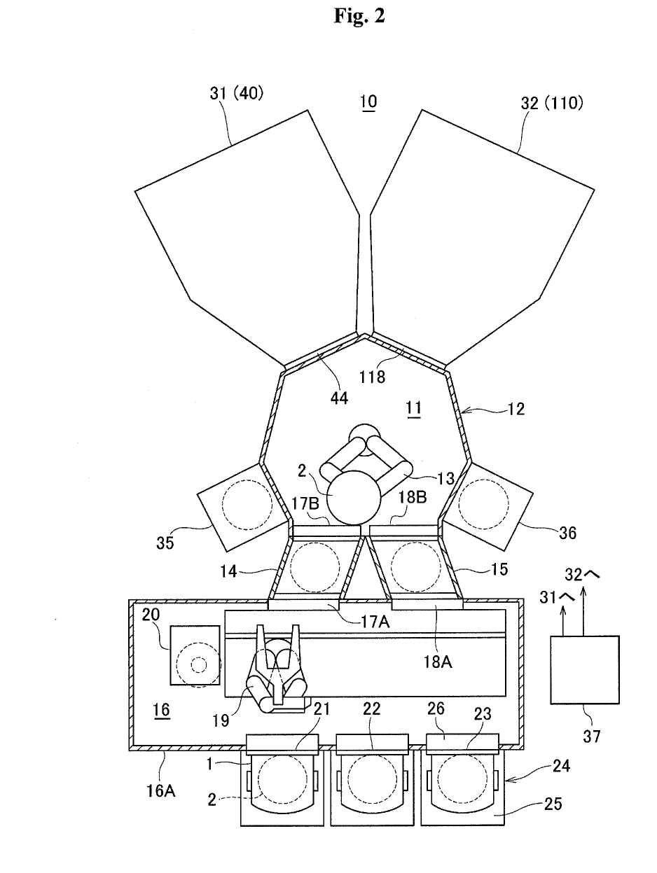

The substrate processing apparatus of the current embodiment is configured as a cluster apparatus as shown in FIG. 2. In the cluster apparatus of the current embodiment, as wafer carrying carriers (substrate containers) configured to carry wafers 2, front opening unified pods (FOUPs) 1 (hereinafter referred to as pods 1) are used.

<Cluster Apparatus>

As shown in FIG. 2, a cluster apparatus 10 includes a first wafer transfer chamber 11 (hereinafter referred to as a negative pressure transfer chamber 11) as a transfer module (carrying chamber) configured to endure a pressure (negative pressure) lower than atmospheric pressure, and when viewed from the top, a case 12 (hereinafter referred to as a negative pressure transfer chamber case 12) of the negative pressure transfer chamber 11 has a heptagonal box shape with closed top and bottom sides. The negative pressure transfer chamber case 12 is configured as a carrying vessel (airtight vessel). At the center part of the negative pressure transfer chamber 11, a wafer transfer machine 13 (hereinafter referred to as a negative pressure transfer machine 13) is installed as a carrying robot configured to transfer a wafer 2 under a negative pressure condition.

As loadlock modules (loadlock chambers), a carrying-in preliminary chamber 14 (hereinafter referred to as a carrying-in chamber 14) and a carrying-out preliminary chamber 15 (hereinafter referred as a carrying-out chamber 15) are closely disposed and connected to the biggest sidewall (front wall) of the seven sidewalls of the negative pressure transfer chamber case 12. When viewed from the top, each of a case of the carrying-in chamber 14 and a case of the carrying-out chamber 15 is formed in an approximately rhombic shape with closed top and bottom sides and is configured as a loadlock chamber capable of enduring a negative pressure condition.

A second wafer transfer chamber 16 (hereinafter referred to as a positive pressure transfer chamber 16), which is a front end module configured to be kept at a pressure equal to or higher than atmospheric pressure (hereinafter referred to as a positive pressure), is connected to sides of the carrying-in chamber 14 and the carrying-out chamber 15 opposite to the negative pressure transfer chamber 11, and when viewed from the top, a case of the positive pressure transfer chamber 16 has a horizontally elongated rectangular shape with closed top and bottom sides. Between the carrying-in chamber 14 and the positive pressure transfer chamber 16, a gate valve 17A is installed, and between the carrying-in chamber 14 and the negative pressure transfer chamber 11, a gate valve 17B is installed. Between the carrying-out chamber 15 and the positive pressure transfer chamber 16, a gate valve 18A is installed, and between the carrying-out chamber 15 and the negative pressure transfer chamber 11, a gate valve 18B is installed. In the positive pressure transfer chamber 16, a second wafer transfer machine 19 (hereinafter referred to as a positive pressure transfer machine 19) is installed as a carrying robot configured to transfer a wafer 2 under a positive pressure condition. The positive pressure transfer machine 19 is configured to be moved upward and downward by an elevator installed at the positive pressure transfer chamber 16, and is also configured to reciprocate left and right by a linear actuator. At the left end part of the positive pressure transfer chamber 16, a notch aligning device 20 is installed.

At the front wall of the positive pressure transfer chamber 16, three wafer carrying entrances 21, 22, and 23 are formed in a closed arranged fashion so that wafers 2 can be carried into and out of the positive pressure transfer chamber 16 through the wafer carrying entrances 21, 22, and 23. Pod openers 24 are installed at the wafer carrying entrances 21, 22, and 23, respectively. Each of the pod openers 24 includes a stage 25 on which a pod 1 can be placed, and a cap attachment/detachment mechanism 26 configured to attach and detach a cap of a pod 1 placed on the stage 25. By attaching or detaching a cap of a pod 1 placed on the stage 25 using the pod opener 24, a wafer taking in/out entrance of the pod 1 can be closed or opened. Pods 1 are supplied to the stages 25 of the pod openers 24 and taken away from the stages 25 of the pod openers 24 by an in-process carrying device (rail guided vehicle, RGV).

As shown in FIG. 2, as processing modules, a first processing unit 31 (high permittivity insulation film forming unit 31) and a second processing unit 32 (heat treatment unit 32) are closely disposed and respectively connected to two sidewalls (rear walls) of the seven sidewalls of the negative pressure transfer chamber case 12 opposite to the positive pressure transfer chamber 16. Between the first processing unit 31 and the negative pressure transfer chamber 11, a gate valve 44 is installed. Between the second processing unit 32 and the negative pressure transfer chamber 11, a gate valve 118 is installed. In addition, as cooling stages, a first cooling unit 35 and a second cooling unit 36 are respectively connected to two sidewalls of the seven sidewalls of the negative pressure transfer chamber case 12 that face the positive pressure transfer chamber 16, and each of the first and second cooling units 35 and 36 functions as a cooling chamber for cooling a processed wafer 2.

The cluster apparatus 10 includes a main controller 37 for overall controlling of a substrate processing flow (described later). The main controller 37 controls each part of the cluster apparatus 10.

<First Processing Unit>

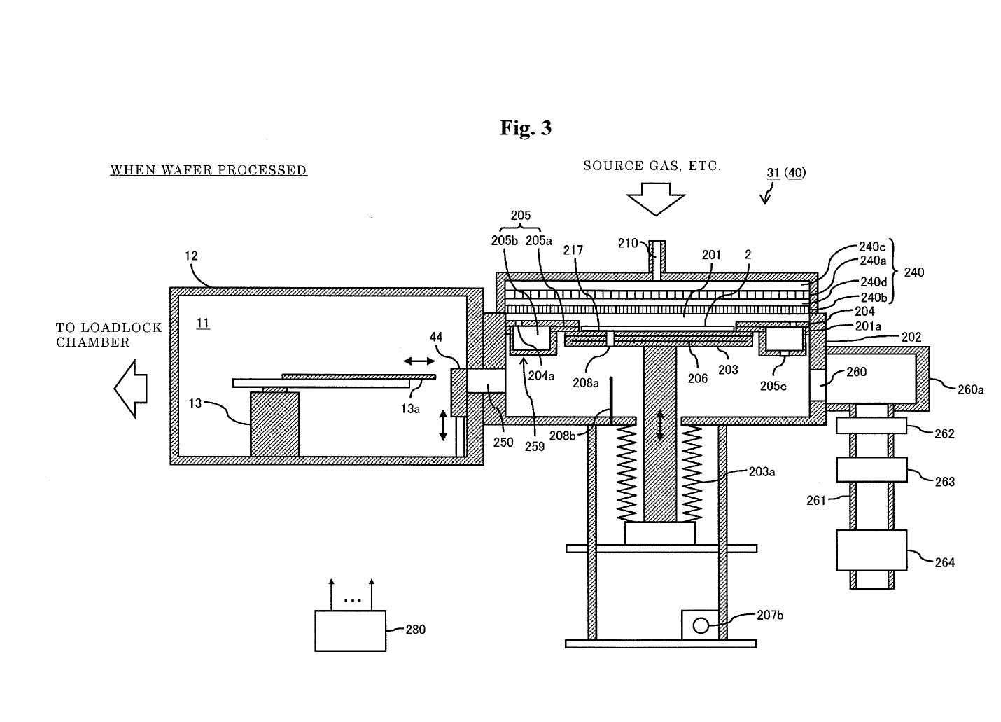

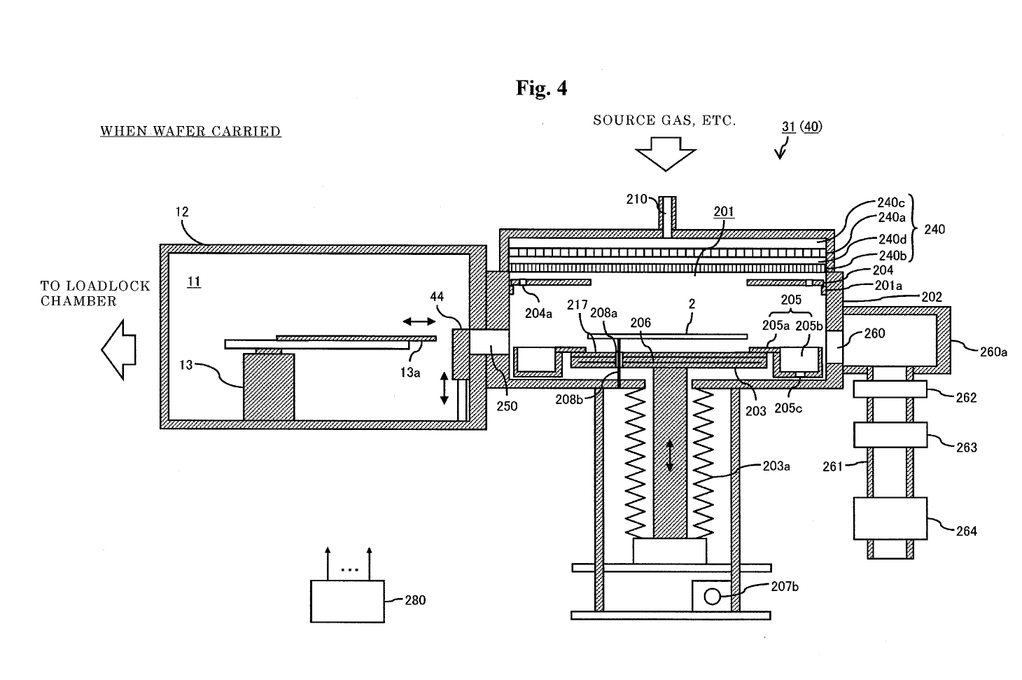

Next, an explanation will be given on the first processing unit 31 of the cluster apparatus 10 according to the current embodiment. The first processing unit 31 is a high permittivity insulation film forming unit, and as shown in FIG. 3 and FIG. 4, the first processing unit 31 is configured as a single wafer type cold wall substrate processing apparatus. Functionally, the first processing unit 31 is configured as an atomic layer deposition (ALD) apparatus 40 (hereinafter referred to as a film-forming apparatus 40). Hereinafter, the structure of the film-forming apparatus 40 will be described with reference to FIG. 3 and FIG. 4. FIG. 3 is a sectional view illustrating the film-forming apparatus 40 when a wafer 2 is processed, and FIG. 4 is a sectional view illustrating the film-forming apparatus 40 when a wafer 2 is carried.

[Processing Chamber]

As shown in FIG. 3 and FIG. 4, the film-forming apparatus 40 includes a processing vessel 202. For example, the processing vessel 202 is a flat airtight vessel having a circular cross sectional shape. The processing vessel 202 is made of a material such as aluminum (Al) or stainless steel (e.g., SUS described in the Japanese industrial standard). In the processing vessel 202, a processing chamber 201 is formed to process a wafer 2 which is a substrate.

[Support Stage]

In the processing chamber 201, a support stage 203 is installed to support a wafer 2. On the top surface of the support stage 203 that makes direct contact with the wafer 2, a susceptor 217 made of a material such as quartz (SiO₂), carbon, a ceramic material, silicon carbide (SiC), aluminum oxide (Al₂O₃), or aluminum nitride (AlN) is installed as a support plate. In the support stage 203, a heater 206 is built as a heating unit (heating source) configured to heat the wafer 2. The lower end part of the support stage 203 penetrates the bottom side of the processing vessel 202.

At the outside of the processing chamber 201, an elevating mechanism 207b is installed to elevate the support stage 203. By operating the elevating mechanism 207b to raise and lower the support stage 203, the wafer 2 supported on the susceptor 217 can be raised and lowered. When the wafer 2 is carried, the support stage 203 is lowered to a position (wafer carrying position) shown in FIG. 4, and when the wafer 2 is processed, the support stage 203 is raised to a position (wafer processing position) shown in FIG. 3. The lower end part of the support stage 203 is surrounded by a bellows 203a so that the inside of the processing chamber 201 can be hermetically maintained.

In addition, on the bottom surface (floor surface) of the processing chamber 201, for example, three lift pins 208b are installed in a manner such that the lift pins 208b are vertically erected. Furthermore, in the support stage 203 (including the susceptor 217), penetration holes 208a are respectively formed at positions corresponding to the lift pins 208b so that the lift pins 208b can be inserted through the penetration holes 208a. In addition, when the support stage 203 is lowered to the wafer carrying position, as shown in FIG. 4, upper parts of the lift pins 208b protrude from the top surface of the susceptor 217 so that the lift pins 208b can support the wafer 2 the bottom side of the wafer 2. In addition, when the support stage 203 is raised to the wafer processing position, as shown in FIG. 3, the lift pins 208b are retracted from the top surface of the susceptor 217 so that the susceptor 217 can support the wafer 2 from the bottom side of the wafer 2. Since the lift pins 208b make direct contact with the wafer 2, it is preferable that the lift pins 208b be made of a material such as quartz or alumina.

At a side of the inner wall of the processing chamber 201 (processing vessel 202), a wafer carrying entrance 250 is installed so that a wafer 2 can be carried into and out of the processing chamber 201 through wafer carrying entrance 250. At the wafer carrying entrance 250, the gate valve 44 is installed so that the inside of the processing chamber 201 can communicate with the inside of the negative pressure transfer chamber 11 by opening the gate valve 44. In the negative pressure transfer chamber 11, the negative pressure transfer machine 13 is installed, and the negative pressure transfer machine 13 includes a carrying arm 13a configured to support a wafer 2 when carrying the wafer 2. In a state where the support stage 203 is lowered to the wafer carrying position, the gate valve 44 is opened, and then the negative pressure transfer machine 13 can transfer a wafer 2 between the inside of the processing chamber 201 and the inside of the negative pressure transfer chamber 11. A wafer 2 carried into the processing chamber 201 is temporarily placed on the lift pins 208b as described above.

[Exhaust System]

At a side of the inner wall of the processing chamber 201 (processing vessel 202) opposite to the wafer carrying entrance 250, an exhaust outlet 260 is installed for exhaust the inside atmosphere of the processing chamber 201. An exhaust pipe 261 is connected to the exhaust outlet 260 through an exhaust chamber 260a. At the exhaust pipe 261, a pressure regulator 262 such as an auto pressure controller (APC) configured to control the inside pressure of the processing chamber 201, a source collection trap 263, and a vacuum pump 264 are sequentially connected in series. An exhaust system (exhaust line) is constituted mainly by the exhaust outlet 260, the exhaust chamber 260a, the exhaust pipe 261, the pressure regulator 262, the source collection trap 263, and the vacuum pump 264.

[Gas Entrance]

At the top surface (the ceiling wall) of a later-described shower head 240 installed at an upper part of the processing chamber 201, a gas inlet 210 is installed to introduce various gases into the processing chamber 201. A gas supply system connected to the gas inlet 210 will be described later.

[Shower Head]

Between the gas inlet 210 and a wafer 2 placed at the wafer processing position, a shower head 240 is installed as a gas distributing mechanism. The shower head 240 includes a distributing plate 240a configured to distribute a gas introduced through the gas inlet 210, and a shower plate 240b configured to distribute the gas passing through the distributing plate 240a more uniformly and supply the gas to the surface of the wafer 2 placed on the support stage 203. A plurality of ventilation holes are formed in the distributing plate 240a and the shower plate 240b. The distributing plate 240a is disposed to face the top surface of the shower head 240 and the shower plate 240b, and the shower plate 240b is disposed to face the wafer 2 placed on the support stage 203. Between the top surface of the shower head 240 and the distributing plate 240a and between the distributing plate 240a and the shower plate 240b, spaces are provided which function as a first buffer space (distributing chamber) 240c through which gas supplied through the gas inlet 210 is distributed and a second buffer space 240d through which gas passing through the distributing plate 240a is diffused.

[Exhaust Duct]

On the side surface of the inner wall of the processing chamber 201, a stopper 201a is installed. The stopper 201a is configured to hold a conductance plate 204 at a position close to the wafer processing position. The conductance plate 204 is a doughnut-shaped (ring-shaped) circular disk having an opening to accommodate the wafer 2 along its inner circumferential part. A plurality of discharge outlets 204a are formed in the outer circumferential part of the conductance plate 204 in a manner such that the discharge outlets 204a are arranged at predetermined intervals in the circumferential direction of the conductance plate 204. The discharge outlets 204a are discontinuously formed so that the outer circumferential part of the conductance plate 204 can support the inner circumferential part of the conductance plate 204.

A lower plate 205 latches onto the outer circumferential part of the support stage 203. The lower plate 205 includes a ring-shaped concave part 205b and a flange part 205a formed in one piece with the inner upper side of the concave part 205b. The concave part 205b is installed to close a gap between the outer circumferential part of the support stage 203 and the side surface of the inner wall of the processing chamber 201. At a part of the lower side of the concave part 205b close to the exhaust outlet 260, a plate exhaust outlet 205c is formed to discharge (distribute) gas from the inside of the concave part 205b toward the exhaust outlet 260. The flange part 205a functions as a latching part that latches onto the upper outer circumferential part of the support stage 203. Since the flange part 205a latches onto the upper outer circumferential part of the support stage 203, the lower plate 205 can be lifted together with the support stage 203 when the support stage 203 is lifted.

When the support stage 203 is raised to the wafer processing position, the lower plate 205 is also raised to the wafer processing position. As a result, the top surface of the concave part 205b is blocked by the conductance plate 204 held at a position close to the wafer processing position, and thus a gas flow passage region is formed in the concave part 205b as an exhaust duct 259. At this time, by the exhaust duct 259 (the conductance plate 204 and the lower plate 205) and the support stage 203, the inside of the processing chamber 201 is divided into an upper processing chamber higher than the exhaust duct 259 and a lower processing chamber lower than the exhaust duct 259. Preferably, the conductance plate 204 and the lower plate 205 may be formed of a material that can be held at a high temperature, for example, high temperature resistant and high load resistant quartz.

An explanation will now be given on a gas flow in the processing chamber 201 during a wafer processing process. First, a gas supplied from the gas inlet 210 to the upper side of the shower head 240 flows from the first buffer space 240c to the second buffer space 240d through the plurality of holes of the distributing plate 240a, and is then supplied to the inside of the processing chamber 201 through the plurality of holes of the shower plate 240b, so that the gas can be uniformly supplied to the wafer 2. The gas supplied to the wafer 2 flows outward in the radial directions of the wafer 2. After the gas makes contact with the wafer 2, remaining gas is discharged to the exhaust duct 259 disposed at the outer circumference of the wafer 2: that is, the remaining gas flows outward on the conductance plate 204 in the radial directions of the wafer 2 and is discharged to the gas flow passage region (the inside of the concave part 205b) of the exhaust duct 259 through the discharge outlets 204a formed in the conductance plate 204. Thereafter, the gas flows in the exhaust duct 259 and is exhaust through the plate exhaust outlet 205c and the exhaust outlet 260. Since gas is directed to flow in this manner, the gas can be prevented from flowing to the lower part of the processing chamber 201, that is, the rear side of the support stage 203 or the bottom side of the processing chamber 201.

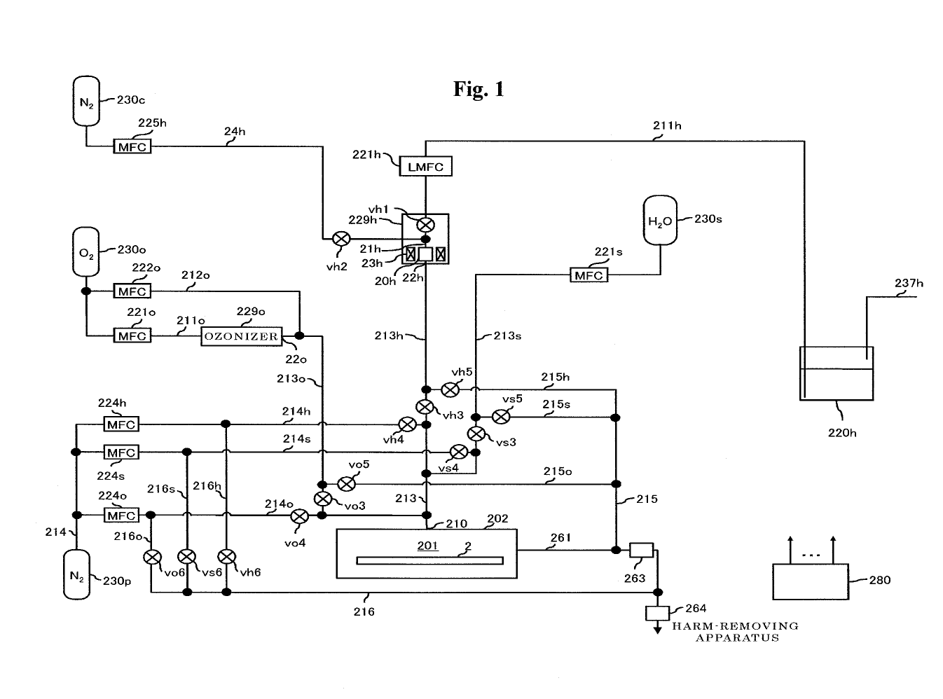

Next, the configuration of the gas supply system connected to the gas inlet 210 will be described with reference to FIG. 1. FIG. 1 illustrates the configuration of the gas supply system (gas supply lines) of the film-forming apparatus 40 according to the current embodiment.

[Source Supply System]

At the outside of the processing chamber 201, a liquid source supply source 220h is installed to supply a hafnium (Hf)-containing organic metal liquid source (hereinafter referred to as a Hf source) as a liquid source. The liquid source supply source 220h is configured as a tank (airtight reservoir) in which a liquid source can be contained (filled).

A pressurizing gas supply pipe 237h is connected to the liquid source supply source 220h. A pressurizing gas supply source (not shown) is connected to the upstream end part of the pressurizing gas supply pipe 237h.

In addition, the downstream end part of the pressurizing gas supply pipe 237h communicates with an inside upper space of the liquid source supply source 220h, so as to supply a pressurizing gas to the space. Preferably, a gas that does not react with the liquid source may be used as the pressurizing gas. For example, inert gas such as N₂ gas may be suitable as the pressurizing gas.

In addition, a liquid source supply pipe 211h is connected to the liquid source supply source 220h. The upstream end part of the liquid source supply pipe 211h is placed in the liquid source contained in the liquid source supply source 220h. Furthermore, the downstream end part of the liquid source supply pipe 211h is connected to a vaporizer 229h which is a vaporizing unit configured to vaporizing the liquid source. Furthermore, at the liquid source supply pipe 211h, a liquid mass flow controller (LMFC) 221h is installed as a flow rate controller for controlling the supply flow rate of the liquid source, and a valve vh1 is installed to control supply of the liquid source. The valve vh1 is installed in the vaporizer 229h.

In the above-described structure, by opening the valve vh1 and simultaneously supplying a pressurizing gas through the pressurizing gas supply pipe 237h, the liquid source can be pressurized (supplied) from the liquid source supply source 220h to the vaporizer 229h. A liquid source supply system (liquid source supply line) is constituted mainly by the liquid source supply source 220h, the pressuring gas supply pipe 237h, the liquid source supply pipe 211h, the LMFC 221h, and the valve vh1.

The vaporizer 229h includes a vaporizing chamber 20h in which a source gas is generated by vaporizing the liquid source using a heater 23h, a liquid source flow passage 21h as a flow passage through which the liquid source is discharged into the vaporizing chamber 20h, the valve vh1 for controlling supply of the liquid source into the vaporizing chamber 20h, and an outlet 22h through which a source gas generated in the vaporizing chamber 20h is supplied to a source gas supply pipe 213h (described later). The downstream end part of the liquid source supply pipe 211h is connected to the upstream end part of the liquid source flow passage 21h through the valve vh1. The downstream end part end part of a carrier gas supply pipe 24h is connected to the liquid source flow passage 21h so as to supply a carrier gas from the carrier gas supply pipe 24h to the vaporizing chamber 20h through the liquid source flow passage 21h. The upstream end part of the carrier gas supply pipe 24h is connected to a N₂ gas supply source 230c that supplies N₂ gas as a carrier gas. At the carrier gas supply pipe 24h. At the carrier gas supply pipe 24h, an MFC 225h is installed as a flow rate controller for controlling the supply flow rate of N₂ gas, and a valve vh2 is installed to control supply of the N₂ gas.

The upstream end part of the source gas supply pipe 213h is connected to the outlet 22h of the vaporizer 229h to supply a source gas to the inside of the processing chamber 201. The downstream of the source gas supply pipe 213h is connected to the gas inlet 210 through a confluent pipe 213. In addition, at the source gas supply pipe 213h, a valve vh3 is installed to control supply of a source gas into the processing chamber 201.

In the above-described structure, the liquid source is vaporized to generate a source gas, and the valve vh3 is simultaneously opened, so that the source gas can be supplied from the source gas supply pipe 213h to the inside of the processing chamber 201 through the confluent pipe 213. A source gas supply system (source gas supply line) is constituted mainly by the source gas supply pipe 213h and the valve vh3. In addition, a source supply system (Hf source supply system) is constituted mainly by the liquid source supply system, the vaporizing unit, and the source gas supply system.

[First Oxidizing Source Supply System]

At the outside of the processing chamber 201, a H₂O gas supply source 230s is installed to supply H₂O gas as a first oxidizing source (oxidant). The upstream end part of a H₂O gas supply pipe 213s is connected to the H2O gas supply source 230s. The downstream end part of the H₂O gas supply pipe 213s is connected to the confluent pipe 213. That is, the H₂O gas supply pipe 213s is configured to supply H₂O gas to the inside of the processing chamber 201. At the H₂O gas supply pipe 213s, an MFC 221s is installed as a flow rate controller for controlling the supply flow rate of H₂O gas, and a valve vs3 is installed for controlling supply of the H₂O gas into the processing chamber 201. A first oxidizing source supply system (H₂O supply system) is constituted mainly by the H₂O gas supply source 230s, the H₂O gas supply pipe 213s, the MFC 221s, and the valve vs3.

[Second Oxidizing Source Supply System]

In addition, at the outside of the processing chamber 201, an O₂ gas supply source 230o is installed to supply O₂ gas as a source of O₃ gas which is a second oxidizing source (oxidant). The upstream end part of an O₂ gas source pipe 211o is connected to the O₂ gas supply source 230o. An ozonizer 229o is connected to the downstream end part of the O₂ gas supply pipe 211o to generate O₃ gas from O₂ gas by using plasma as a second oxidizing source. At the O₂ gas supply pipe 211o, an MFC 221o is installed as a flow rate controller for controlling the supply flow rate of O₂ gas.

The upstream end part of an O₃ gas supply pipe 213o is connected to an outlet 22o of the ozonizer 229o. The downstream end part of the O₃ gas supply pipe 213o is connected to the confluent pipe 213. That is, the O₃ gas supply pipe 213o is configured to supply O₃ gas into the processing chamber 201. In addition, at the O₃ gas supply pipe 213o, a valve vo3 is installed to control supply of O₃ gas into the processing chamber 201.

In addition, the upstream end part of an O₂ gas supply pipe 212o is connected to the O₂ gas source pipe 2110 at the upstream side of the MFC 221o. Furthermore, the downstream end part of the O₂ gas supply pipe 212o is connected to the O₃ gas supply pipe 213o at the upstream side of the valve vo3. Furthermore, at the O₂ gas supply pipe 212o, an MFC 222o is installed as a flow rate controller for controlling the supply flow rate of O₂ gas.

In the above-described structure, O₂ gas is supplied to the ozonizer 229o to generate O₃ gas, and the valve vo3 is simultaneously opened, so that O₃ gas can be supplied into the processing chamber 201. In addition, when O₃ gas is supplied into the processing chamber 201, if O₂ gas is supplied through the O₂ gas supply pipe 212o, the O₃ gas is diluted with the O₂ gas and is then supplied into the processing chamber 201 so that the concentration of the O₃ gas can be controlled. A second oxidizing source supply system (O₃ supply system) is constituted mainly by the O₂ gas supply source 230o, the O₂ gas supply pipe 211o, the ozonizer 229o, the MFC 221o, the O₃ gas supply pipe 213o, the valve vo3, the O₂ gas supply pipe 212o, and the MFC 222o.

[Purge Gas Supply System]

In addition, at the outside of the processing chamber 201, a N₂ gas supply source 230p is installed to supply N₂ gas as a purge gas. The upstream end part of a purge gas supply pipe 214 is connected to the N₂ gas supply source 230p. The downstream end part of the purge gas supply pipe 214 branches into three lines: purge gas supply pipes 214h, 214s, and 214o. The downstream end parts of the purge gas supply pipes 214h, 214s, and 214o are connected to the downstream sides of the valves vh3, vs3, and vo3 of the source gas supply pipe 213h, the H₂O gas supply pipe 213s, and the O₃ gas supply pipe 213o, respectively. At the purge gas supply pipes 214h, 214s, and 214o, MFCs 224h, 224s, and 224o are respectively installed as flow rate controllers for controlling the supply flow rates of N₂ gas, and valves vh4, vs4, and vo4 are respectively installed to control supplies of N₂ gas. A purge gas supply system (purge gas supply line) is constituted mainly by the N₂ gas supply source 230p, the purge gas supply pipes 214, 214h, 214s, and 214o, the MFCs 224h, 224s, and 224o, and the valves vh4, vs4, and vo4.

[Vent System]

In addition, the upstream end parts of vent pipes 215h, 215s, and 215o are connected to the upstream sides of the valves vh3, vs3, and vo3 of the source gas supply pipe 213h, the H₂O gas supply pipe 213s, and the O₃ gas supply pipe 213o, respectively. Furthermore, the downstream end parts of the vent pipes 215h, 215s, and 215o are joined together into a vent pipe 215, and the vent pipe 215 is connected to the upstream side of the source collection trap 263 of the exhaust pipe 261. At the vent pipes 215h, 215s, and 215o, valves vh5, vs5, and vo5 are respectively installed to control supplies of gases.

In the above-described structure, by closing the valves vh3, vs3, and vo3, and opening the valves vh5, vs5, and vo5, gases flowing in the source gas supply pipe 213h, the H₂O gas supply pipe 213s, and the O₃ gas supply pipe 213o can be bypassed to the outside of the processing chamber 201 without supplying the gases into the processing chamber 201.

In addition, vent pipes 216h, 216s, and 216o are respectively connected to the downstream sides of the MFCs 224h, 224s, and 224o which are located at the upstream sides of the valves vh4, vs4, and vo4 of the purge gas supply pipes 214h, 214s, and 214o. The downstream sides of the vent pipes 216h, 216s, and 216o are joined together into a vent pipe 216, and the vent pipe 216 is connected to the downstream side of the source collection trap 263 of the exhaust pipe 261 but the upstream side of the vacuum pump 264. At the vent pipes 216h, 216s, and 216o, valves vh6, vs6, and vo6 are installed to control supplies of gas.

In the above-described structure, by closing the valves vh4, vs4, and vo4, and opening the valves vh6, vs6, and vo6, N₂ gas flowing in the purge gas supply pipes 214h, 214s, and 214o can be bypassed to the outside of the processing chamber 201 without supplying the N₂ gas into the processing chamber 201. In the case where the valves vh3, vs3, and vo3 are closed and the valves vh5, vs5, and vo5 are opened so as to bypass gases flowing in the source gas supply pipe 213h, the H₂O gas supply pipe 213s, and the O₃ gas supply pipe 213o to the outside of the processing chamber 201 without supplying the gases into the processing chamber 201, the valves vh4, vs4, and vo4 are opened to introduce N₂ gas into the source gas supply pipe 213h, the H₂O gas supply pipe 213s, and the O₃ gas supply pipe 213o for purging the insides of the supply pipes 213h, 213s, and 213o. In addition, the valves vh6, vs6, and vo6 are set to be operated in reverse to the valves vh4, vs4, and vo4 so that when N₂ gas is not supplied to the source gas supply pipes 213h, 213s, and 213o, the N₂ gas can be exhausted by bypassing the processing chamber 201. A vent system (vent lines) is constituted mainly by the vent pipes 215h, 215s, 215o, and 215, the vent pipes 216h, 216s, 216o, and 216, and valves vh5, vs5, and vo5, and valves vh6, vs6, and vo6.

[Controller]

The film-forming apparatus 40 includes a controller 280 configured to control each part of the film-forming apparatus 40. Under the control of the main controller 37, the controller 280 controls operations of parts such as the gate valve 44, the elevating mechanism 207b, the negative pressure transfer machine 13, the heater 206, the pressure regulator 262, the vaporizer 229h, the ozonizer 229o, the vacuum pump 264, the valves vh1 to vh6, vs3 to vs6, and vo3 to vo6, the LMFC 221h, and the MFCs 225h, 221s, 221o, 222o, 224h, 224s, and 224o. <Second Processing Unit>

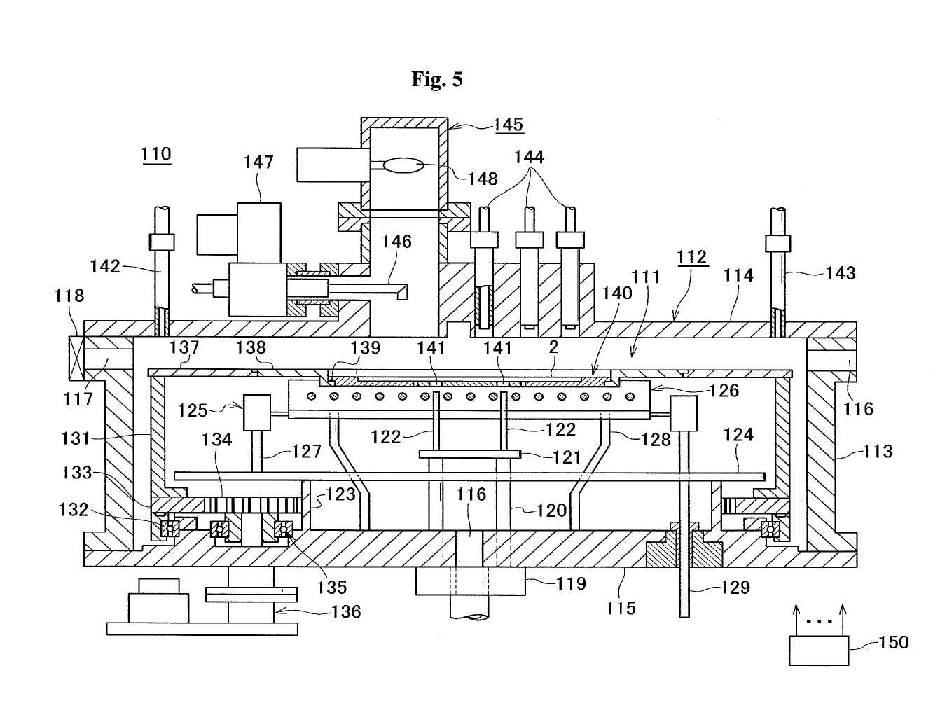

Next, an explanation will be given on the second processing unit 32 of the cluster apparatus 10 according to the current embodiment. In the current embodiment, the second processing unit 32 is a heat treatment unit, and as shown in FIG. 5, the second processing unit 32 is configured as a single wafer type cold wall substrate processing apparatus. Functionally, the second processing unit 32 is configured as a rapid thermal processing apparatus (hereinafter referred to as an RTP apparatus) 110. Hereinafter, the structure of the RTP apparatus 110 will be described with reference to FIG. 5. FIG. 5 is a sectional view illustrating the RTP apparatus 110 when a wafer is processed.

As shown in FIG. 5, the RTP apparatus 110 includes a case 112 as a processing vessel in which a processing chamber 111 is formed to process a wafer 2. The case 112 has a hollow cylindrical shape formed by: a tube 113 having a cylindrical shape with opened top and bottom sides; a top plate 114 having a circular disk shape and configured to close the opened top side of the tube 113; and a bottom plate 115 having a circular disk shape and configured to close the opened bottom side of the tube 113. In a part of the sidewall of the tube 113, an exhaust outlet 116 is formed to connect the inside and outside of the processing chamber 111. An exhaust device is connected to the exhaust outlet 116 to exhaust the inside of the processing chamber 111 to a pressure lower than atmospheric pressure (hereinafter referred to as a negative pressure). At a position of the sidewall of the tube 113 opposite to the exhaust outlet 116, a wafer carrying entrance 117 is formed to carry the wafer 2 into and out of the processing chamber 111, and the wafer carrying entrance 117 is configured to be opened and closed by the gate valve 118.

Along the centerline of the bottom surface of the bottom plate 115, an elevating drive device 119 is installed. The elevating drive device 119 is configured to lift and lower elevating shafts 120 which are inserted through the bottom plate 115 in a vertically slidable manner. An elevating plate 121 is horizontally fixed to the upper ends of the lower elevating shafts 120, and a plurality of lift pins 122 (usually, three or four lift pins) are vertically erected and fixed to the top surface of the elevating plate 121. The lift pins 122 are lifted and lowered according to the lifting and lowering motions of the elevating plate 121 so as to horizontally support the bottom side of the wafer 2 and lift and lower the wafer 2.

On the top surface of the bottom plate 115, a support cylinder 123 is protruded at the outside of the lower elevating shafts 120, and on the top surface of the support cylinder 123, a cooling plate 124 is horizontally installed. Above the cooling plate 124, a first heating lamp group 125 and a second heating lamp group 126 that are constituted by a plurality of heating lamps are sequentially disposed from the lower side, and each of the first and second heating lamp groups 125 and 126 is horizontally installed. The first heating lamp group 125 and the second heating lamp group 126 are horizontally supported by first pillars 127 and second pillars 128, respectively. A power supply line 129 for the first heating lamp group 125 and the second heating lamp group 126 is inserted through the bottom plate 115 and extended to the outside.

In the processing chamber 111, a turret 131 is disposed concentrically with the processing chamber 111. The turret 131 is concentrically fixed to the top surface of an internal spur gear 133. The internal spur gear 133 is horizontally supported on a bearing 132 installed at the bottom plate 115.

The internal spur gear 133 is engaged with a drive spur gear 134. The drive spur gear 134 is horizontally supported on a bearing 135 installed at the bottom plate 115 and is configured to be rotated by a susceptor rotating device 136 installed under the bottom plate 115. On the top surface of the turret 131, an outer platform 137 having a flat circular ring shape is horizontally installed. Inside the outer platform 137, an inner platform 138 is horizontally installed. A susceptor 140 is engaged to and held by an engagement part 139 protruding radially from the lower part of the inner circumference of the inner platform 138. Penetration holes 141 are formed in the susceptor 140 at positions corresponding to the lift pins 122.

An annealing gas supply pipe 142 and an inert gas supply pipe 143 are connected to the top plate 114 in a manner such that the annealing gas supply pipe 142 and the inert gas supply pipe 143 can communicate with the inside of the processing chamber 111. A plurality of probes 144 of a radiation thermometer are inserted in the top plate 114 in a manner such that the probes 144 are staggered in radial directions from the center to the periphery of the wafer 2 and face the top surface of the wafer 2. The radiation thermometer is configured such that temperatures detected by the probes 144 from light radiated from the wafer 2 are sequentially transmitted to a controller 150. The controller 150 compares the temperatures measured by the probes 144 with a set temperature and controls the supply amount of power to the first heating lamp group 125 and the second heating lamp group 126.

At another position of the top plate 114, an emissivity measuring device 145 is installed to measure the emissivity of the wafer 2 in a noncontact manner. The emissivity measuring device 145 includes a reference probe 146. The reference probe 146 is configured to be rotated on a vertical plane by a reference probe motor 147. Above the reference probe 146, a reference lamp 148 configured to radiate reference light is installed to face the tip of the reference probe 146. The reference probe 146 measures the temperature of the wafer 2 by comparing radiation from the reference lamp 148 and radiation from the wafer 2. Wafer temperatures measured by the probes 144 are corrected by comparing them with a temperature measured by the reference probe 146, so that wafer temperatures can be precisely detected.

The controller 150 is configured to control each part of the RTP apparatus 110. In addition, the controller 150 is controlled by the main controller 37.

### (2) Substrate Processing Process

Next, an explanation will be given on a method of processing a wafer 2 using the above-described cluster apparatus 10 as one of semiconductor device manufacturing processes (substrate processing process). In the following description, an explanation will be given on an exemplary case of processing a wafer 2 on which a titanium nitride (TiN) film is formed as a lower electrode of a capacitor. Furthermore, in the following description, each part of the cluster apparatus 10 is controlled by the main controller 37.

A cap of a pod 1 placed on the stage 25 of the cluster apparatus 10 is detached by the cap attachment/detachment mechanism 26, and thus a wafer taking in/out entrance of the pod 1 is opened. After the pod 1 is opened, the positive pressure transfer machine 19 installed at the positive pressure transfer chamber 16 picks up wafers 2 one by one from the pod 1 through the wafer carrying entrance and carries the wafers 2 to the carrying-in chamber 14 where the wafers 2 are placed on a carrying-in chamber temporary stage. During this operation, the gate valve 17A disposed at a side of the carrying-in chamber 14 facing the positive pressure transfer chamber 16 is in an opened state; the gate valve 17B disposed at the other side of the carrying-in chamber 14 facing the negative pressure transfer chamber 11 is in a closed state; and the inside of the negative pressure transfer chamber 11 is kept at 100 Pa, for example.

The side of the carrying-in chamber 14 facing the positive pressure transfer chamber 16 is closed by the gate valve 17A, and the carrying-in chamber 14 is exhaust to a negative pressure by an exhaust device. When the inside pressure of the carrying-in chamber 14 is reduced to a preset pressure, the gate valve 17B disposed at the other side of the carrying-in chamber 14 facing the negative pressure transfer chamber 11 is opened. Next, the negative pressure transfer machine 13 of the negative pressure transfer chamber 11 picks up the wafers 2 one by one from the carrying-in chamber temporary stage and carries the wafers 2 into the negative pressure transfer chamber 11. Thereafter, the gate valve 17B disposed at the other side of the carrying-in chamber 14 facing the negative pressure transfer chamber 11 is closed. Subsequently, the gate valve 44 of the first processing unit 31 is opened, and the negative pressure transfer machine 13 loads the wafer 2 into processing chamber 201 of the first processing unit 31 (wafer loading). When the wafer 2 is loaded into the processing chamber 201, since the carrying-in chamber 14 and the negative pressure transfer chamber 11 are previously vacuum-evacuated, permeation of oxygen or moisture into the processing chamber 201 can be surely prevented.

<Film-Forming Process>

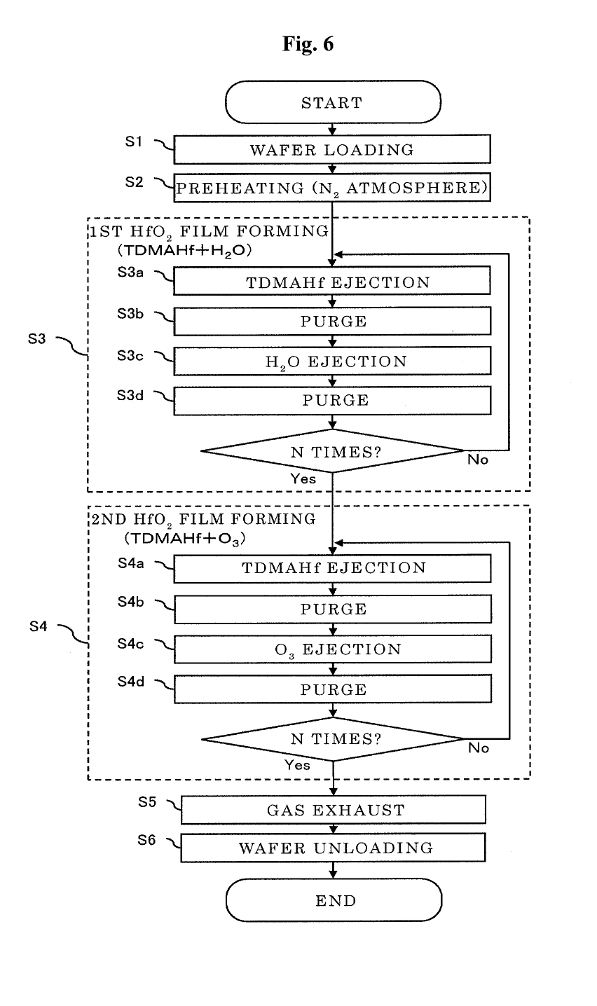

Next, with reference to FIG. 6, an explanation will be given on a film-forming process for forming a high permittivity insulation film as a capacitor insulation film on the lower electrode of the wafer 2 by using the first processing unit 31 (film-forming apparatus 40). FIG. 6 is a flowchart for explaining a film-forming process according to an embodiment of the present invention. In the following description, TDMAHf (Tetrakis-Dimethyl-Amino-Hafnium: Hf[N(CH₃)₂]₄) which is a Hf precursor is used as a source, H₂O is used as a first oxidizing source, and O₃ is used as a second oxidizing source, so as to form a hafnium oxide (HfO₂) film as a high permittivity insulation film by an ALD method. Furthermore, in the following description, each part of the film-forming apparatus 40 is controlled by the controller 280. In addition, the operation of the controller 280 is controlled by the main controller 37.

[Wafer Loading Process S1]

First, the elevating mechanism 207b is operated to lower the support stage 203 to the wafer carrying position as shown in FIG. 4. Then, as described above, the gate valve 44 is opened so that the processing chamber 201 can communicate with the negative pressure transfer chamber 11. Next, as described above, the wafer 2 is loaded from the negative pressure transfer chamber 11 into the processing chamber 201 by using the negative pressure transfer machine 13 in a state where the wafer 2 is supported on the carrying arm 13a (S1). The wafer 2 loaded in the processing chamber 201 is temporarily placed on the lift pins 208b protruding upward from the top surface of the support stage 203. If the carrying arm 13a of the negative pressure transfer machine 13 is returned from the processing chamber 201 to the negative pressure transfer chamber 11, the gate valve 44 is closed.

Next, the elevating mechanism 207b is operated to raise the support stage 203 to the wafer processing position as shown in FIG. 3. As a result, the lift pins 208b are retracted from the top surface of the support stage 203, and the wafer 2 is placed on the susceptor 217 disposed at the top surface of the support stage 203.

[Preheating Process S2]

Next, the pressure regulator 262 adjusts the inside pressure of the processing chamber 201 to a predetermined processing pressure. In addition, power supplied to the heater 206 is adjusted to heat the wafer 2 and increase the surface temperature of the wafer 2 to a predetermined processing temperature (S2).

In the wafer loading process S1, the preheating process S2, and an unloading process S6 (described later), while the vacuum pump 264 is operated, the valves vh3, vs3, and vo3 are closed and the valves vh4, vs4, and vo4 are opened to allow N₂ gas to flow into the processing chamber 201 so as to previously keep the inside of the processing chamber 201 at a N₂ gas atmosphere. By this, attachment of particles to the wafer 2 can be suppressed. The vacuum pump 264 is continuously operated at least from the wafer loading process 51 to the wafer unloading process S6 (described later).

Along with the processes S1 and S2, a source gas (Hf source gas), that is, generation of a TDMAHf gas is started in advance (pre-vaporization) by vaporizing TDMAHf which is a liquid source (Hf source). That is, in a state where the valve vh3 is closed, while supplying a carrier gas to the vaporizer 229h by opening the valve vh2, the valve vh1 is opened, and at the same time, a pressurizing gas is supplied through the pressuring gas supply pipe 237h to pressurize (supply) the liquid source from the liquid source supply source 220h to the vaporizer 229h and generate a source gas by vaporizing the liquid source at the vaporizer 229h. In this pre-vaporization process, while operating the vacuum pump 264, the valve vh5 is opened in a state where the valve vh3 is closed so that the source gas is not supplied into to the processing chamber 201 but is exhausted through a route bypassing the processing chamber 201.

In addition, generation of H₂O gas which is a first oxidizing source (first oxidizing gas) is also started in advance. That is, while operating the vacuum pump 264, the valve vs5 is opened in a state where the valve vs3 is closed so that H₂O gas is not supplied into the processing chamber 201 but is exhausted through a route bypassing the processing chamber 201.

In addition, preferably, generation of O₃ gas which is a second oxidizing source (second oxidizing gas) is also started in advance. That is, O₂ gas is supplied from the O₂ gas supply source 230o to the ozonizer 229o to generate O₃ gas at the ozonizer 229o. At this time, while operating the vacuum pump 264, the valve vo5 is opened in a state where the valve vo3 is closed so that O₃ gas is not supplied into the processing chamber 201 but is exhausted through a route bypassing the processing chamber 201.

It takes time to stably generate source gas from the vaporizer 229h, H₂O gas from the H₂O gas supply source 230s, or O₃ gas from the ozonizer 229o. That is, when source gas, H₂O gas, and O₃ gas are initially generated, they are unstably supplied. Therefore, in the current embodiment, generation of source gas, H₂O gas, and O₃ gas are started in advance for obtaining earlier stable supply state, and in this stable supply state, the valves vh3, vh5, vs3, vs5, vo3, and vo5 are switched to change flow passages of the source gas, H₂O gas, and O₃ gas. Therefore, by switching valves, stable supply of the source gas, H₂O gas, and O₃ gas into the processing chamber 201 can be quickly started and stopped, which is a preferable result.

[First HfO₂ Film Forming Process S3]

[TDMAHf Ejection Process S3a]

Next, the valves vh4 and vh5 are closed, and valve vh3 is opened so as to supply TDMAHf gas into the processing chamber 201 as a source gas. That is, ejection of TDMAHf gas to the wafer 2 is started. The source gas is distributed by the shower head 240 so that the source gas can be uniformly supplied to the wafer 2 disposed in the processing chamber 201. Surplus source gas flows in the exhaust duct 259 and is exhausted to the exhaust outlet 260. When the source gas is supplied into the processing chamber 201, so as to prevent permeation of the source gas into the H₂O gas supply pipe 213s and the O₃ gas supply pipe 213o and facilitate diffusion of the source gas in the processing chamber 201, it is preferable that the valves vs4 and vo4 be kept in an opened state to continuously supply N₂ gas into the processing chamber 201. After a predetermined time from the start of supply of the source gas by opening the valve vh3, the valve vh3 is closed, and the valves vh4 and vh5 are opened to stop supply of the source gas into the processing chamber 201.

[Purge Process S3b]

After the valve vh3 is closed to stop supply of the source gas into the processing chamber 201, supply of N₂ gas is continued in a state where the valves vh4, vs4, and vo4 are in an opened state. The N₂ gas is supplied into the processing chamber 201 through the shower head 240 and flows in the exhaust duct 259 where the N₂ gas is exhausted to the exhaust outlet 260. In this way, the inside of the processing chamber 201 is purged with N₂ gas, and source gas remaining in the processing chamber 201 is removed.

[H₂O Ejection Process S3c]

After the inside of the processing chamber 201 is completely purged, the valves vs4 and vs5 are closed, and the valve vs3 is opened so as to supply H₂O gas into the processing chamber 201 as a first oxidizing source. That is, ejection of H₂O gas to the wafer 2 is started. The H₂O gas is distributed by the shower head 240 so that the H₂O gas can be uniformly supplied to the wafer 2 disposed in the processing chamber 201. Surplus H₂O gas flows in the exhaust duct 259 and is exhausted to the exhaust outlet 260. When the H₂O gas is supplied into the processing chamber 201, so as to prevent permeation of the H₂O gas into the source gas supply pipe 213h and the O₃ gas supply pipe 213o and facilitate diffusion of the H₂O gas in the processing chamber 201, it is preferable that the valves vh4 and vo4 be kept in an opened state to continuously supply N₂ gas into the processing chamber 201. After a predetermined time from the start of supply of the H₂O gas by opening the valve vs3, the valve vs3 is closed, and the valves vs4 and vs5 are opened to stop supply of the H₂O gas into the processing chamber 201.

[Purge Process S3d]

After the valve vs3 is closed to stop supply of the H₂O gas into the processing chamber 201, supply of N₂ gas is continued in a state where the valves vh4, vs4, and vo4 are in an opened state. The N₂ gas is supplied into the processing chamber 201 through the shower head 240 and flows in the exhaust duct 259 where the N₂ gas is exhausted to the exhaust outlet 260. In this way, the inside of the processing chamber 201 is purged with N₂ gas, and H₂O gas or reaction byproducts remaining in the processing chamber 201 are removed.

[Repetition Process S3e]

Thereafter, the processes S3a to S3d are set as one cycle, and this cycle is repeated predetermined times, so as to form a first HfO₂ film (as an initial layer) on the wafer 2 (that is, on the TiN film (lower electrode) of the wafer 2) to a predetermined thickness as a first high permittivity insulation film.

In a film-forming temperature range of an ALD method, H₂O gas used as an oxidizing source in the first HfO₂ film forming process S3 has less energy and oxidizing power than O₃ gas. Therefore, in a film-forming temperature condition of an ALD method, oxidation of the lower electrode can be reduced by using H₂O gas as an oxidizing source as compared with the case of using O₃ gas as an oxidizing source. As a result, deterioration of the lower electrode can be prevented. For example, a decrease in the capacitance of a capacitor can be prevented.

If the thickness of the first HfO₂ film formed in the first HfO₂ film forming process S3 is too small, the lower electrode may easily be oxidized by O₃ gas used as an oxidizing source in a second HfO₂ film forming process S4 (described later). Therefore, preferably, in the first HfO₂ film forming process S3, the above-described cycle may be repeated ten or more times, and a first HfO₂ film having a thickness of 1 nm or greater may be formed.

In addition, if the thickness of the first HfO₂ film formed in the first HfO₂ film forming process S3 is too large, the productivity of the film-forming process may be decreased due to the following reason. H₂O gas is easily adsorbed onto inside members of the processing chamber 201 but is difficult to be removed as compared with O₃ gas, and thus it takes more time to discharge H₂O gas from the processing chamber 201 than to discharge O₃ gas from the processing chamber 201. Therefore, preferably, in the first HfO₂ film forming process S3, the above-described cycle may be repeated forty times or fewer, and a first HfO₂ film having a thickness of 4 nm or smaller may be formed. That is, as long as oxidation of the lower electrode caused by O₃ gas used in a second HfO₂ film forming process S4 can be suppressed by the thickness of the first HfO₂ film, it is preferable that the thickness of the first HfO₂ film be as small as possible.

[Second HfO₂ Film Forming Process S4]

[TDMAHf Ejection Process S4a]

Next, like in the TDMAHf ejection process S3a of the first HfO₂ film forming process S3, TDMAHf gas is ejected to the wafer 2.

[Purge Process S4b]

Thereafter, like in the purge process S3b of the first HfO₂ film forming process S3, the inside of the processing chamber 201 is purged. [O₃ Ejection Process S4c]

After the inside of the processing chamber 201 is completely purged, the valves vo4 and vo5 are closed, and the valve vo3 is opened so as to supply O₃ gas into the processing chamber 201 as a second oxidizing source. The O₃ gas is distributed by the shower head 240 so that the O₃ gas can be uniformly supplied to the wafer 2 disposed in the processing chamber 201. Surplus O₃ gas or reaction byproducts are allowed to flow in the exhaust duct 259 and are exhausted to the exhaust outlet 260. When the O₃ gas is supplied into the processing chamber 201, so as to prevent permeation of the O₃ gas into the source gas supply pipe 213h and the H₂O gas supply pipe 213s and facilitate diffusion of the O₃ gas in the processing chamber 201, it is preferable that the valves vh4 and vs4 be kept in an opened state to continuously supply N₂ gas into the processing chamber 201. After a predetermined time from the start of supply of the O₃ gas by opening the valve vo3, the valve vo3 is closed, and the valves vo4 and vo5 are opened to stop supply of the O₃ gas into the processing chamber 201.

[Purge Process S4d]

After the valve vo3 is closed to stop supply of the O₃ gas into the processing chamber 201, supply of N₂ gas is continued in a state where the valves vh4, vs4, and vo4 are in an opened state. The N₂ gas is supplied into the processing chamber 201 through the shower head 240 and flows in the exhaust duct 259 where the N₂ gas is exhausted to the exhaust outlet 260. In this way, the inside of the processing chamber 201 is purged with N₂ gas, and O₃ gas or reaction byproducts remaining in the processing chamber 201 are removed.

[Repetition Process S4e]

Thereafter, the processes S4a to S4d are set as one cycle, and this cycle is repeated predetermined times, so as to form a second HfO₂ film having a predetermined thickness on the first HfO₂ film of the wafer 2 as a second high permittivity insulation film. In this way, a HfO₂ film having a predetermined thickness is formed on the wafer 2 (on the TiN film (lower electrode) of the wafer 2) as a high permittivity insulation film. The HfO₂ film having a predetermined thickness is constituted by the first HfO₂ film and the second HfO₂ film.

When the first HfO₂ film forming process S3 and the second HfO₂ film forming process S4 are performed according to an ALD method, the processing temperature (wafer temperature) is controlled in a range where the source gas does not decompose by itself In this case, in the TDMAHf ejection processes S3a and S4a, TDMAHf is adsorbed onto the wafer 2. In the H₂O ejection process S3c, H₂O reacts with TDMAHf adsorbed onto the wafer 2, and thus a HfO₂ film having less than one atomic layer is formed on the wafer 2. In the O₃ ejection process S4c, O₃ reacts with TDMAHf adsorbed onto the wafer 2, and thus a HfO₂ film having less than one atomic layer is formed on the wafer 2. At this time, impurities such as carbon (C) and hydrogen (H) that tend to permeate a thin film can be removed owing to the O₃.

In the film-forming apparatus of the current embodiment, when a first HfO₂ film is formed by an ALD method, the following exemplary processing conditions may be used. Wafer temperature: 100° C. to 400° C., processing chamber pressure: 1 Pa to 1000 Pa, TDMAHf supply flow rate: 10 sccm to 2000 sccm, H₂O supply flow rate: 10 sccm to 2000 sccm, N₂ (purge gas) supply flow rate: 10 sccm to 10000 sccm, and film thickness: 1 nm to 4 nm.

Furthermore, in the film-forming apparatus of the current embodiment, when a second HfO₂ film is formed by an ALD method, the following exemplary processing conditions may be used. Wafer temperature: 100° C. to 400° C., processing chamber pressure: 1 Pa to 1000 Pa, TDMAHf supply flow rate: 10 sccm to 2000 sccm, O₃ supply flow rate: 10 sccm to 2000 sccm, N₂ (purge gas) supply flow rate: 10 sccm to 10000 sccm, and total film thickness of first and second HfO₂ films: 8 nm to 12 nm.

[Gas Exhaust Process S5]

After the HfO₂ film is formed to a predetermined thickness, the inside of the processing chamber 201 is vacuum-evacuated. Alternatively, while supplying inert gas into the processing chamber 201, the inside of the processing chamber 201 is vacuum-evacuated and purged.

Thereafter, the inside atmosphere of the processing chamber 201 is replaced with inert gas.

[Wafer Unloading Process S6]

After that, in the reverse order to that of the wafer loading process S1, the wafer 2 on which the HfO₂ film is formed to a predetermined thickness is unloaded from the processing chamber 201 to the negative pressure transfer chamber 11.

<Heat Treatment Process>

Next, an explanation will be given on a heat treatment process for heat-treating a HfO₂ film having a predetermined thickness and formed on a wafer 2 by using the second processing unit 32 (RTP apparatus 110). That is, an explanation will be given on a process of annealing a HfO₂ film having a predetermined thickness under an inert gas atmosphere to make the HfO₂ film dense or crystallize the HfO₂ film. In the following description, each part of the RTP apparatus 110 is controlled by the controller 150, and the controller 150 is controlled by the main controller 37.

After the gate valve 44 is closed in the wafer unloading process S6, the gate valve 118 is opened. After the gate valve 118 is opened, a wafer 2 to be processed by annealing is loaded into the processing chamber 111 of the RTP apparatus 110 (second processing unit 32) through the wafer carrying entrance 117 and is placed on the upper ends of the lift pins 122 by the negative pressure transfer machine 13. If the negative pressure transfer machine 13 is moved backward from the processing chamber 111 after the negative pressure transfer machine 13 places the wafer 2 on the lift pins 122, the wafer carrying entrance 117 is closed by the gate valve 118. In addition, the lower elevating shafts 120 are lowered by the elevating drive device 119 such that the wafer 2 is transferred from the lift pins 122 to the top of the susceptor 140. In a state where the processing chamber 111 is hermetically closed, the inside of the processing chamber 111 is exhausted through the exhaust outlet 116 to a predetermined pressure in the range from 1 Pa to 1000 Pa.

After the wafer 2 is transferred to the susceptor 140, the turret 131 holding the wafer 2 with the susceptor 140 is rotated by the susceptor rotating device 136. While the wafer 2 held on the susceptor 140 is rotated by the susceptor rotating device 136, the wafer 2 is heated to a predetermined temperature in the range from 400° C. to 700° C. by the first heating lamp group 125 and the second heating lamp group 126. During the rotation and heating, inert gas such as nitrogen gas or argon gas is supplied into the processing chamber 111 through the annealing gas supply pipe 142. At this time, the supply flow rate of the inert gas is adjusted to a predetermined value in the range from 10 sccm to 10000 sccm. Since the wafer 2 is uniformly heated by the first heating lamp group 125 and the second heating lamp group 126 while the susceptor 140 is rotated by the susceptor rotating device 136, the entire surface of a HfO₂ film having a predetermined thickness and formed on the wafer 2 is uniformly annealed. The annealing treatment may be performed for a predetermined time in the range from 1 second to 60 seconds. By this heat treatment, the HfO₂ film having a predetermined thickness and formed on the wafer 2 is densified or crystallized.

After a preset process time of the RTP apparatus 110, the inside of the processing chamber 111 is exhausted to a predetermined negative pressure through the exhaust outlet 116, and then the gate valve 118 is opened. Thereafter, the annealed wafer 2 is unloaded from the processing chamber 111 to the negative pressure transfer chamber 11 by the negative pressure transfer machine 13 in the reverse order to the loading order.

After the wafer 2 is processed through the high permittivity insulation film forming process and the heat treatment process, if necessary, the wafer 2 may be cooled in the first cooling unit 35 or the second cooling unit 36.

Thereafter, the side of the carrying-out chamber 15 facing the negative pressure transfer chamber 11 is opened by the gate valve 18B, and the negative pressure transfer machine 13 carries the wafer 2 from the negative pressure transfer chamber 11 to the carrying-out chamber 15 where the wafer 2 is transferred to a carrying-out chamber temporary stage. For this, the side of the carrying-out chamber 15 facing the positive pressure transfer chamber 16 is previously closed by the gate valve 18A, and the carrying-out chamber 15 is exhausted to a negative pressure by an exhaust device. After the pressure of the carrying-out chamber 15 is decreased to a preset value, the side of the carrying-out chamber 15 facing the negative pressure transfer chamber 11 is opened by the gate valve 18B, and the wafer 2 is unloaded. After the wafer 2 is unloaded, the gate valve 18B is closed.

By repeating the above-described actions, twenty five wafers 2 batch-loaded in the carrying-in chamber 14 can be sequentially processed through the above-described processes. After the twenty five wafers 2 are sequentially processed, the processed wafers 2 are collected on the temporary stage of the carrying-out chamber 15.

Thereafter, nitrogen gas is supplied into the carrying-out chamber 15 which is kept at a negative pressure so as to adjust the inside pressure of the carrying-out chamber 15 to atmospheric pressure, and then the side of the carrying-out chamber 15 facing the positive pressure transfer chamber 16 is opened by the gate valve 18A. Next, a cap of an empty pod 1 placed on the stage 25 is opened by the attachment/detachment mechanism 26 of the pod opener 24. Subsequently, the positive pressure transfer machine 19 of the positive pressure transfer chamber 16 picks up the wafers 2 from the carrying-out chamber 15 to the positive pressure transfer chamber 16 and carries the wafers 2 into the pod 1 through the wafer carrying entrance 23 of the positive pressure transfer chamber 16. After the processed twenty five wafers 2 are carried into the pod 1, the cap of the pod 1 is attached to the wafer taking in/out entrance of the pod 1 by the cap attachment/detachment mechanism 26 of the pod opener 24 so that the pod 1 is closed.

In the current embodiment, wafers 2 processed through sequential processes in the cluster apparatus 10 are hermetically accommodated in a pod 1, and are then carried to another film-forming apparatus that performs an upper electrode forming process.

### (3) Effects of Current Embodiment

According to the current embodiment, one or more of the following effects can be obtained.

According to the current embodiment, in the first HfO₂ film forming process S3, TDMAHf gas and H₂O gas are alternately ejected to a wafer 2 so that a first HfO₂ film having a predetermined thickness can be formed as an initial layer on a TiN film (lower electrode) of the wafer 2. In a film-forming temperature range of an ALD method, H₂O gas has less energy and oxidizing power than O₃ gas. Therefore, in a film-forming temperature condition of an ALD method, oxidation of a lower electrode can be reduced by using H₂O gas as an oxidizing source as compared with the case of using O₃ gas as an oxidizing source. As a result, deterioration of a lower electrode can be prevented. For example, a decrease in the capacitance of a capacitor can be prevented.

Furthermore, according to the current embodiment, in the second HfO₂ film forming process S4, TDMAHf gas and O₃ gas are alternately supplied to the wafer 2 so as to form a second HfO₂ film having a predetermined thickness on the first HfO₂ film of the wafer 2. Sine O₃ gas is not easily adsorbed onto inside members of the processing chamber 201 but is easily removed as compared with H₂O gas, O₃ gas can be discharged from the processing chamber 201 in a shorter time than H₂O gas. Therefore, the productivity of the film-forming process can be improved. In addition, by using O₃ gas as an oxidizing source, the characteristics of a high permittivity insulation film can be improved as compared with the case of using only H₂O gas as an oxidizing source.

As described above, according to the current embodiment, in an initial process of forming a HfO₂ film (a process of forming a first HfO₂ film to a thickness of several nanometers or less, preferably, in the range from 1 nm to 4 nm), H₂O gas is used as an oxidizing source so as to suppress oxidation of a under-layer metal film such as a TiN film. In addition, after the first HfO₂ film is formed as an initial layer, O₃ gas is used as an oxidizing source to form a second HfO₂ film with improved productivity of the film-forming process. For example, a thin film is formed to a total thickness (the sum of the thicknesses of the first and second HfO₂ films) of 8 nm to 12 nm. By this, deterioration of the lower electrode can be prevented, and the productivity of a semiconductor device manufacturing process can be improved.

In addition, according to the current embodiment, by using the RTP apparatus 110 as the second processing unit 32, a heat treatment process is performed on the HfO₂ film having a predetermined thickness and formed on the wafer 2. By this, the HfO₂ film can be densified or crystallized.

### Example

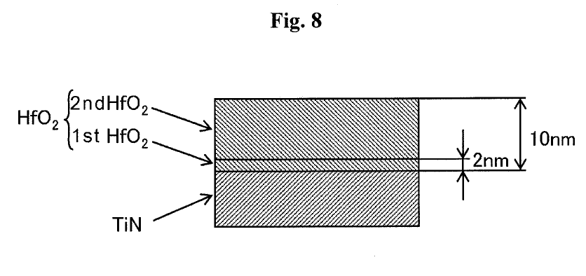

According to the method explained in the above-described embodiments, the inventors have formed a HfO₂ film including first and second HfO₂ films on a TiN film formed on a wafer as a lower electrode. In the film-forming process, TDMAHf, a precursor of Hf, was used as a source; H₂O was used as a first oxidizing source; and O₃ was used as a second oxidizing source. Processing conditions were selected within the processing condition ranges described in the above embodiments. The thickness of the first HfO₂ film was set to 2 nm, and the total thickness of the HfO₂ film (the sum of the thicknesses of the first and second HfO₂ films) was set to 10 nm. FIG. 8 is a schematic sectional view of a sample film of this example.

As a result, it could be found that the TiN film (lower electrode) was almost not oxidized. In addition, the time necessary for discharging O₃ gas from the processing chamber 201 was merely 1/n or less times (n=2 to 6) the time necessary for discharging H₂O gas from the processing chamber 201, and it could be understood that the productivity of the film-forming process could be improved as compared with the case of using only H₂O gas as an oxidizing source.

### Another Embodiment of the Invention

In the above-described embodiment, an explanation has been given on the exemplary case of forming a film by a single wafer type ALD apparatus which is a substrate processing apparatus (film-forming apparatus) configured to process substrates one by one. However, the present invention is not limited thereto. For example, films can be formed by using a substrate processing apparatus such as a batch type vertical ALD apparatus configured to process a plurality of substrates at a time. Hereinafter, a vertical ALD apparatus will be described.

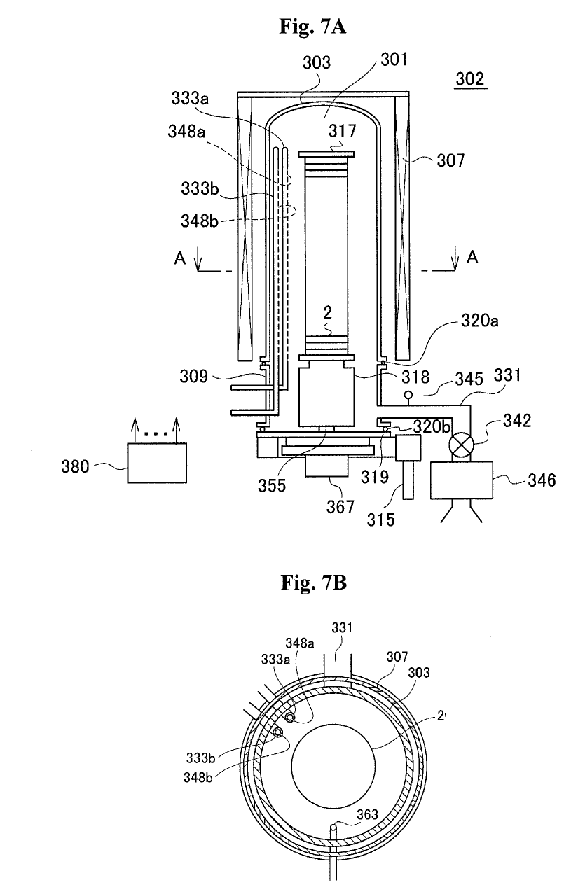

FIG. 7A and FIG. 7B are schematic views illustrating a vertical processing furnace 302 of a vertical ALD apparatus according to an embodiment of the present invention, in which FIG. 7A is a vertical sectional view illustrating the vertical processing furnace 302 and FIG. 7B is a sectional view of the vertical processing furnace 302 taken along line A-A of FIG. 7A.

As shown in FIG. 7A, the processing furnace 302 includes a heater 307 as a heating unit (heating mechanism). The heater 307 has a cylindrical shape and is supported on a holding plate such as a heater base so that the heater 307 can be vertically fixed.

Inside the heater 307, a process tube 303 is installed concentrically with the heater 307 as a reaction tube. The process tube 303 is made of a heat-resistant material such as quartz (SiO₂) and silicon carbide (SiC) and has a cylindrical shape with a closed top side and an opened bottom side. In the hollow part of the process tube 303, a processing chamber 301 is formed, which is configured to accommodate substrates such as wafers 2 in a state where the wafers 2 are horizontally positioned and vertically arranged in multiple stages in a boat 317 (described later).

At the lower side of the process tube 303, a manifold 309 is installed concentrically with the process tube 303. The manifold 309 is made of a material such as stainless steel and has a cylindrical shape with opened top and bottom sides. The manifold 309 is engaged with the process tube 303 and installed to support the process tube 303. Between the manifold 309 and the process tube 303, an O-ring 320a is installed as a seal member. The manifold 309 is supported by the heater base such that the process tube 303 can be vertically fixed. The process tube 303 and the manifold 309 constitute a reaction vessel.

A first nozzle 333a as a first gas introducing part, and a second nozzle 33b as a second gas introducing part are connected to the manifold 309 in a manner such that the first and second nozzles 333a and 333b penetrate the sidewall of the manifold 309. Each of the first and second nozzles 333a and 333b has an L-shape with a horizontal part and a vertical part. The horizontal part is connected to the manifold 309, and the vertical part is erected in an arc-shaped space between the inner wall of the process tube 303 and the wafers 2 along the inner wall of the process tube 303 from the bottom side to the top side in the arranged direction of the wafers 2.In the lateral sides of the vertical parts of the first and second nozzles 333a and 333b, first gas supply holes 348a and second gas supply holes 348b are formed, respectively. The first and second gas supply holes 348a and 348b have the same size and are arranged at the same pitch from the lower side to the upper side.

The same gas supply systems as those explained in the previous embodiment are connected to the first and second nozzles 333a and 333b. However, the current embodiment is different form the previous embodiment, in that the source gas supply pipe 213h is connected to the first nozzle 333a, and the H₂O gas supply pipe 213s and the O₃ gas supply pipe 213o are connected to the second nozzle 333b. In the current embodiment, a source gas and an oxidizing source (H₂O or O₃) are supplied through different nozzles. In addition, respective oxidizing sources may be supplied through different nozzles.

At the manifold 309, an exhaust pipe 331 is installed to exhaust the inside atmosphere of the processing chamber 301. A vacuum exhaust device such as a vacuum pump 346 is connected to the exhaust pipe 331 through a pressure detector such a pressure sensor 345 and a pressure regulator such as an auto pressure controller (APC) valve 342, and based on pressure information detected by the pressure sensor 345, the APC valve 342 is controlled so that the inside of the processing chamber 301 can be vacuum-evacuated to a predetermined pressure (vacuum degree). The APC valve 342 is an on-off valve configured to be opened and closed to start and stop vacuum evacuation of the inside of the processing chamber 301, and configured to be adjusted in valve opening degree for adjusting the inside pressure of the processing chamber 301.

At the lower side of the manifold 309, a seal cap 319 is installed as a furnace port cover capable of hermetically closing the opened bottom side of the manifold 309. The seal cap 319 is configured to be brought into contact with the manifold 309 in a vertical direction from the bottom side of the manifold 309. The seal cap 319 is made of a metal such as stainless steel and has a circular disk shape. On the top surface of the seal cap 319, an O-ring 320b is installed as a seal member configured to make contact with the bottom side of the manifold 309. At a side of the seal cap 319 opposite to the processing chamber 301, a rotary mechanism 367 is installed to rotate the boat 317 (described later). A rotation shaft 355 of the rotary mechanism 367 is inserted through the seal cap 319 and is connected to the boat 317, so as to rotate the wafers 2 by rotating the boat 317. The seal cap 319 is configured to be vertically moved by a boat elevator 315 which is disposed at the outside of the process tube 303 as an elevating mechanism, and by this, the boat 317 can be loaded into and out of the processing chamber 301.

The boat 317 which is a substrate holding tool is made of a heat-resistant material such as quartz or silicon carbide and is configured to hold a plurality of wafers 2 in a state where the wafers 2 are horizontally positioned and arranged in multiple stages with the centers of the wafers 2 being aligned. At the lower part of the boat 317, an insulating member 318 made of a heat-resistant material such as quartz or silicon carbide is installed so as to prevent heat transfer from the heater 307 to the seal cap 319. In the process tube 303, a temperature sensor 363 is installed as a temperature detector, and based on temperature information detected by the temperature sensor 363, power supplied to the heater 307 is controlled to obtain a desired temperature distribution in the processing chamber 301. Like the first nozzle 333a and the second nozzle 333b, the temperature sensor 363 is installed along the inner wall of the process tube 303.

A controller 380 which is a control unit (control part) is configured to control operations of parts such as the APC valve 342, the heater 307, the temperature sensor 363, the vacuum pump 346, the rotary mechanism 367, the boat elevator 315, the valves vh1 to vh6, vs3 to vs6, and vo3 to vo6, the LMFC 221h, and the MFCs 225h, 221s, 221o, 222o, 224h, 224s, and 224o.

Next, an explanation will be given on a substrate processing process for forming a thin film on a wafer 2 by an ALD method using the processing furnace 302 of the vertical ALD apparatus, as one of semiconductor device manufacturing processes. In the following description, each part of the vertical ALD apparatus is controlled by the controller 380.

A plurality of wafers 2 are charged into the boat 317 (wafer charging). Then, as shown in FIG. 7A, the boat 317 in which the plurality of wafers 2 are held is lifted and loaded into the processing chamber 301 by the boat elevator 315 (boat loading). In this state, the bottom side of the manifold 309 is sealed by the seal cap 319 with the O-ring 320b being disposed therebetween.

The inside of the processing chamber 301 is vacuum-evacuated by the vacuum pump 346 to a desired pressure (vacuum degree). At this time, the inside pressure of the processing chamber 301 is measured by the pressure sensor 345, and based on the measured pressure, the APC valve 342 is feedback-controlled. In addition, the inside of the processing chamber 301 is heated by the heater 307 to a desired temperature. At this time, so as to obtain a desired temperature distribution in the processing chamber 301, power supplied to the heater 307 is feedback-controlled based on temperature information detected by the temperature sensor 363. Then, the rotary mechanism 367 rotates the boat 317 to rotate the wafers 2.

Thereafter, like in the above-described embodiment, for example, the first HfO₂ film forming process S3 and the second HfO₂ film forming process S4 are performed so as to form HfO₂ films on the wafers 2 to a predetermined thickness.

After that, the boat elevator 315 lowers the seal cap 319 to open the bottom side of the manifold 309 and unload the boat 317 from the process tube 303 through the opened bottom side of the manifold 309 in a state where the wafers 2 on which HfO₂ films having a predetermined thickness are formed are held in the boat 317 (boat unloading). Thereafter, the processed wafers 2 are discharged from the boat 317 (wafer discharging).

According to the current embodiment, the same effects as those obtained in the above-described embodiment can be obtained. That is, deterioration of a lower electrode can be prevented, and the productivity of a semiconductor device manufacturing process can be improved.

### Another Embodiment of the Invention

While the present invention has been particularly described with reference to the embodiments, the present invention is not limited to the embodiments, but various changes and modifications may be made in the present invention without departing from the scope of the invention.

For example, in the above-described embodiments, the case of forming a HfO₂ film as a high permittivity film has been described; however, the present invention is not limited thereto. For example, the present invention may be applied to other cases of forming a HfSiO film, a HfAlO film, a ZrO₂ film, a ZrSiO film, a ZrAlO film, a TiO₂ film, a Nb₂O₅ film, a Ta₂O₅ film, or a combination or mixture thereof as a high permittivity film.

Furthermore, in the above-described embodiments, O₃ gas is used as an oxidizing source when a second HfO₂ film is formed; however, the present invention is not limited thereto. For example, as an oxidizing source, an oxygen-containing material activated by plasma, for example, O₂ gas activated by plasma may be used. In this case, a remote plasma unit may be installed instead of the ozonizer 229o.

Furthermore, in the above-described embodiments, H₂O gas is used as an oxidizing source to form a first HfO₂ film as an initial layer, and then O₃ gas is used as an oxidizing source to form a second HfO₂ film. However, the present invention is not limited thereto. For example, a step of forming a high permittivity film by using H₂O gas as an oxidizing source, and a step of forming a high permittivity film by using O₃ gas as an oxidizing source may be alternately repeated. In another example, a step of forming a high permittivity film by using H₂O gas as an oxidizing source, and a step of forming a high permittivity film by using O₃ gas as an oxidizing source may be repeated while switching from one step to the other in random timing, instead of alternately repeating the steps.

Furthermore, according to the above-described embodiments, in the first HfO₂ film forming process S3, TDMAHf ejection process S3a→Purge process S3b→H₂O ejection process S3c→Purge process S3d are set as one cycle, and this cycle is repeated predetermined times; and in the second HfO₂ film forming process S4, TDMAHf ejection process S4a→Purge process S4b→O₃ gas ejection process S4c→Purge process S4d are set as one cycle, and this cycle is repeated predetermined times. However, the present invention is not limited to the case of starting the cycle from supply of a source gas. For example, the cycle may start from supply of an oxidizing source. That is, in the first HfO₂ film process S3, H₂O ejection process S3c→Purge process S3b→TDMAHf ejection process S3a→Purge process S3d may be set as one cycle, and this cycle may be repeated predetermined times. In the second HfO₂ film process S4, O₃ gas ejection process S4c→Purge process S4b→TDMAHf ejection process S4a→Purge process S4d may be set as one cycle, and this cycle may be repeated predetermined times.

Furthermore, in the above-described embodiments, a high permittivity film forming process and a heat treatment process are performed in different processing vessels (the processing vessel 202 of the film-forming apparatus 40, and the case 112 of the RTP apparatus 110). However, the present invention is not limited thereto. For example, a high permittivity film forming process and a heat treatment process may be performed in the same processing vessel.

According to the method of manufacturing a semiconductor device and the substrate processing apparatus, oxidation of a metal film disposed under a high permittivity insulation film can be suppressed, and the productivity of a film-forming process can be improved.

(Supplementary Note)

The present invention also includes the following preferred embodiments.

According to an embodiment of the present invention, there is provided a method of manufacturing a semiconductor device, the method including:

forming a first high permittivity insulation film on a substrate by alternately repeating a process of supplying a source into a processing chamber in which the substrate is accommodated and exhausting the source from the processing chamber and a process of supplying a first oxidizing source into the processing chamber and exhausting the first oxidizing source from the processing chamber; and

forming a second high permittivity insulation film on the first high permittivity insulation film by alternately repeating a process of supplying the source into the processing chamber and exhausting the source from the processing chamber and a process of supplying a second oxidizing source different from the first oxidizing source into the processing chamber and exhausting the second oxidizing source from the processing chamber.

Preferably, the first oxidizing source may have less energy than the second oxidizing source.

Preferably, the first oxidizing source may have oxidizing power smaller than that of the second oxidizing source.

Preferably, the first oxidizing source may be H₂O, and the second oxidizing source may be O₃ or an oxygen-containing material activated by plasma.

Preferably, the first high permittivity insulation film may have a thickness smaller than that of the second high permittivity insulation film.

Preferably, the first high permittivity insulation film may have a thickness in a range from 1 nm to 4 nm.

Preferably, the first high permittivity insulation film and the second high permittivity insulation film may include the same element (may be the same kind of film).

Preferably, the first high permittivity insulation film and the second high permittivity insulation film may be capacitor insulation films.

Preferably, a metal film may be formed on a surface of the substrate, and the first high permittivity insulation film may be formed on the metal film.

According to another embodiment of the present invention, there is provided a method of manufacturing a semiconductor device, the method including:

forming a first high permittivity insulation film on a substrate by alternately repeating a process of supplying a source into a processing chamber in which the substrate is accommodated and exhausting the source from the processing chamber and a process of supplying H₂O into the processing chamber and exhausting the H₂O from the processing chamber; and

forming a second high permittivity insulation film on the first high permittivity insulation film by alternately repeating a process of supplying the source into the processing chamber and exhausting the source from the processing chamber and a process of supplying O₃ into the processing chamber and exhausting O₃ from the processing chamber.

According to another embodiment of the present invention, there is provided a substrate processing apparatus including:

a processing chamber configured to process a substrate;

a source supply system configured to supply a source into the processing chamber;

a first oxidizing source supply system configured to supply a first oxidizing source into the processing chamber;

a second oxidizing source supply system configured to supply a second oxidizing source different from the first oxidizing source into the processing chamber;

an exhaust system configured to exhaust an inside of the processing chamber; and

a controller configured to control the source supply system, the first oxidizing source supply system, the second oxidizing source supply system, and the exhaust system, so as to:

form a first high permittivity insulation film on the substrate by alternately repeating a process of supplying the source into the processing chamber in which the substrate is accommodated and exhausting the source from the processing chamber and a process of supplying the first oxidizing source into the processing chamber and exhausting the first oxidizing source from the processing chamber; and

form a second high permittivity insulation film on the first high permittivity insulation film by alternately repeating a process of supplying the source into the processing chamber and exhausting the source from the processing chamber and a process of supplying the second oxidizing source into the processing chamber and exhausting the second oxidizing source from the processing chamber.

What is claimed is:

1. A method of manufacturing a semiconductor device, the method comprising:
forming a first high permittivity insulation film on a substrate by alternately repeating a process of supplying a source into a processing chamber in which the substrate is accommodated and exhausting the source from the processing chamber and a process of supplying a first oxidizing source into the processing chamber and exhausting the first oxidizing source from the processing chamber; and
forming a second high permittivity insulation film on the first high permittivity insulation film by alternately repeating a process of supplying the source into the processing chamber and exhausting the source from the processing chamber and a process of supplying a second oxidizing source different from the first oxidizing source into the processing chamber and exhausting the second oxidizing source from the processing chamber.

2. The method of claim 1, wherein the first oxidizing source has less energy than the second oxidizing source.

3. The method of claim 1, wherein the first oxidizing source has oxidizing power smaller than that of the second oxidizing source.

4. The method of claim 1, wherein the first oxidizing source is H₂O, and the second oxidizing source is O₃ or an oxygen-containing material activated by plasma.

5. The method of claim 1, wherein the first high permittivity insulation film has a thickness smaller than that of the second high permittivity insulation film.

6. The method of claim 1, wherein the first high permittivity insulation film has a thickness in a range from 1 nm to 4 nm.

7. The method of claim 1, wherein the first high permittivity insulation film and the second high permittivity insulation film comprise the same element.

8. The method of claim 1, wherein the first high permittivity insulation film and the second high permittivity insulation film are capacitor insulation films.

9. The method of claim 1, wherein a metal film is formed on a surface of the substrate, and the first high permittivity insulation film is formed on the metal film.

10. The method of claim 1, wherein a TiN (titanium nitride) film is formed on a surface of the substrate, and the first high permittivity insulation film is formed on the TiN film.

11. A method of manufacturing a semiconductor device, the method comprising:
forming a first high permittivity insulation film on a substrate by alternately repeating a process of supplying a source into a processing chamber in which the substrate is accommodated and exhausting the source from the processing chamber and a process of supplying H₂O into the processing chamber and exhausting the H₂O from the processing chamber; and
forming a second high permittivity insulation film on the first high permittivity insulation film by alternately repeating a process of supplying the source into the processing chamber and exhausting the source from the processing chamber and a process of supplying O₃ into the processing chamber and exhausting O₃ from the processing chamber.

12. A substrate processing apparatus comprising:
a processing chamber configured to process a substrate;
a source supply system configured to supply a source into the processing chamber;
a first oxidizing source supply system configured to supply a first oxidizing source into the processing chamber;
a second oxidizing source supply system configured to supply a second oxidizing source different from the first oxidizing source into the processing chamber;
an exhaust system configured to exhaust an inside of the processing chamber; and
a controller configured to control the source supply system, the first oxidizing source supply system, the second oxidizing source supply system, and the exhaust system, so as to:
form a first high permittivity insulation film on the substrate by alternately repeating a process of supplying the source into the processing chamber in which the substrate is accommodated and exhausting the source from the processing chamber and a process of supplying the first oxidizing source into the processing chamber and exhausting the first oxidizing source from the processing chamber; and
form a second high permittivity insulation film on the first high permittivity insulation film by alternately repeating a process of supplying the source into the processing chamber and exhausting the source from the processing chamber and a process of supplying the second oxidizing source into the processing chamber and exhausting the second oxidizing source from the processing chamber.
